(19) United States
(12) Patent Application Publication
(10) Pub. No.: US 2025/0356930 A1
(43) Pub. Date: Nov. 20, 2025

(54) TEMPERATURE-BASED READ DISTURB COUNTERS

(71) Applicant: Micron Technology, Inc., Boise, ID (US)

(72) Inventor: Chun Sum Yeung, San Jose, CA (US)

(21) Appl. No.: 19/193,603

(22) Filed: Apr. 29, 2025

Related U.S. Application Data
(60) Provisional application No. 63/647,342, filed on May 14, 2024.

(51) Int. Cl. G11C 16/34; G11C 16/26

(52) U.S. Cl. CPC G11C 16/3431; G11C 16/26; G11C 16/349

(57) ABSTRACT

The present disclosure configures a system component, such as a memory sub-system controller, to provide adaptive media management based on temperature-related memory component capabilities. The controller receives a request to read data from an individual memory component of a set of memory components and, in response, determines a current temperature associated with the memory sub-system. The controller selects an individual multiplier for an individual read disturb (RD) counter associated with the individual memory component based on the current temperature associated with the memory sub-system and increments the individual RD counter based on the individual multiplier to control performance of an individual media management operation.

### PRIORITY APPLICATION

This application claims the benefit of priority to U.S. Provisional Application Ser. No. 63/647,342, filed May 14, 2024, which is incorporated herein by reference in its entirety.

### TECHNICAL FIELD

Examples of the disclosure relate generally to memory sub-systems and, more specifically, to providing temperature-based media management for memory components, such as memory dies or memory blocks.

### BACKGROUND

A memory sub-system can be a storage system, such as a solid-state drive (SSD), and can include one or more memory components that store data. The memory components can be, for example, non-volatile memory components and volatile memory components. In general, a host system can utilize a memory sub-system to store data on the memory components and to retrieve data from the memory components.

### BRIEF DESCRIPTION OF THE DRAWINGS

The present disclosure will be understood more fully from the detailed description given below and from the accompanying drawings of various embodiments of the disclosure.

FIG. 1 is a block diagram illustrating an example computing environment including a memory sub-system, in accordance with some examples.

FIG. 2 is a block diagram of an example media operations manager, in accordance with some examples.

FIGS. 3-4 are flow diagrams of example methods to perform media management operations based on temperature of the memory sub-system, in accordance with some examples.

FIG. 5 is a block diagram illustrating a diagrammatic representation of a machine in the form of a computer system within which a set of instructions can be executed for causing the machine to perform any one or more of the methodologies discussed herein, in accordance with some examples.

### DETAILED DESCRIPTION

The present disclosure configures a system component, such as a memory sub-system controller, to perform memory management operations on different groups of memory components (e.g., memory dies, planes, word lines, and/or memory blocks or sub-blocks) based on their respective read disturb counts adjusted based on temperature. The memory sub-system controller can determine a current temperature of the memory sub-system that includes the memory components and can access a table that maps different memory sub-system temperature ranges with different RD counter multiplier values. The memory sub-system controller can select an individual multiplier for an individual read disturb (RD) counter associated with an individual memory component being read based on the RD counter multiplier value associated with the current temperature obtained from the table. The memory sub-system controller increments the individual RD counter based on the individual multiplier to control performance of an individual media management operation.

This enables the controller to dynamically control the frequency at which read disturb scan operations or other memory management operations are performed for the memory sub-system based on temperature of the memory sub-system, which improves the overall efficiency of operating the memory sub-system. Namely, rather than adjusting the RD counter of the memory components at the same rate regardless of temperature, the memory sub-system controller can adjust that rate on the basis of temperature to avoid having to perform read disturb operations when not necessary or to ensure the read disturb operations are performed in temperature-critical states.

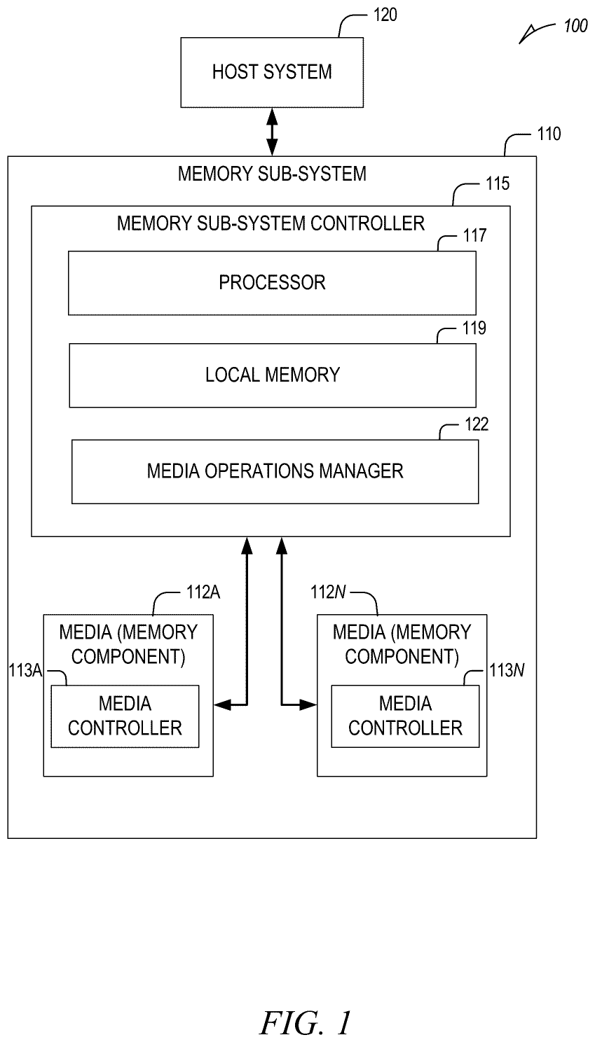

A memory sub-system can be a storage device, a memory module, or a hybrid of a storage device and memory module. Examples of storage devices and memory modules are described below in conjunction with FIG. 1. In general, a host system can utilize a memory sub-system that includes one or more memory components, such as memory devices (e.g., memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data”.

The different memory components (e.g., memory blocks, sub-blocks, word lines, planes, memory dies, and so forth) can each store a respective read count value indicating the quantity or number of times the respective memory component has been read. This read count value can be compared against a read disturb condition criterion (e.g., a read count threshold) which can be used to control when read disturb scan operations are performed for the memory component. Read disturb scan operations involve reading data from one or more portions or specified word lines (WLs) of the memory component and determining whether a read bit error rate (RBER) of the read data transgresses a threshold. If so, the read disturb scan operations refresh or fold the data from the memory component to another memory component. If not, the read disturb scan operations continue monitoring and/or accessing a different memory component and/or memory block.

The memory sub-system can initiate media management operations, such as a write operation, on host data that is stored on a memory device. For example, firmware of the memory sub-system may re-write previously written host data from a location on a memory device to a new location as part of garbage collection management operations. The data that is re-written, for example as initiated by the firmware, is hereinafter referred to as “garbage collection data”. “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management (e.g., read disturb scan operations), different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component. If a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest area that can be erased. Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which is a raw memory device combined with a local embedded controller for memory management within the same memory device package.

There are challenges in efficiently managing or performing media management operations on typical memory devices. Specifically, certain memory devices, such as NAND flash devices, include large die-by-die reliability (RWB) variation and temperature dependence. Certain die can be capable of withstanding (to avoid data loss) particular cross temperatures or temperature ranges while other dies can handle wider temperature ranges. As the technology for such memory devices continues to be scaled down, this die-by-die reliability variation and cross-temperature ranges become more pronounced and problematic in performing memory management. Current memory systems (e.g., SSD drive or die package systems) associate all of the memory devices in the memory system with a certain reliability specification and temperature ranges or thresholds. The memory systems need to meet the reliability specification to be approved for use and cannot include any particular memory device that fails to meet the reliability specification.

Typical memory systems routinely monitor the read count values of different memory blocks to control performing read disturb scan operations. Such read disturb scan operations are usually performed when the read count values of the memory blocks reach a read count threshold or read count threshold value. The read count threshold value is usually set to some predetermined value that ensures the memory blocks are tested for RBER a sufficient number of times. The typical memory systems increment the read count values at the same rate across all of the memory components regardless of temperature responsive to respective read requests. Once those read count values reach the specified threshold, the memory systems perform the RD operations (e.g., test the RBER of the portions being read). While this generally works well, adjusting the counters at the same rate regardless of temperature and using a single non-dynamic RD threshold can result in wasted memory management operations. This is because the RD operations end up being controlled based on a worst performance temperature which can result in unnecessary RD operations being performed. Applying the same read count threshold regardless of the temperature or other conditions can result in performing the read disturb operations unnecessarily in situations where the memory blocks perform well.

As a result, an unnecessary amount of memory management operations can end up being performed on memory dies when not entirely necessary, which can adversely impact the overall performance of the memory system. Also, a lack of performing memory management operations a sufficient quantity of times can result in data loss or high RBER. Current memory systems fail to provide a solution that addresses the needs of all memory devices and applications based on current temperature ranges of the memory devices and/or memory blocks. Applying a one-size-fits all approach, as in the current memory systems, results in poor memory performance and added inefficiencies, which wastes resources.

The present disclosure addresses the above and other deficiencies by providing a memory controller that can determine a current temperature of the memory sub-system that includes the memory components and can access a table that maps different memory sub-system temperature ranges with different RD counter multiplier values. The memory sub-system controller can select an individual multiplier for an individual RD counter associated with an individual memory component being read based on the RD counter multiplier value associated with the current temperature obtained from the table. The memory sub-system controller increments the individual RD counter based on the individual multiplier to control performance of an individual media management operation. This increases the efficiency of operating memory systems because the memory controller dynamically selects or sets the frequency at which read disturb scan operations or other memory management operations are performed for the memory sub-system based on temperature of the memory sub-system, which improves the overall efficiency of operating the memory sub-system. Rather than adjusting the RD counter of the memory components at the same rate regardless of temperature, the memory sub-system controller can adjust that rate on the basis of temperature to avoid having to perform read disturb operations when not necessary.

For some examples, the memory sub-system (e.g., memory sub-system controller) receives a request to read data from an individual memory component of the set of memory components. The controller, in response to receiving the request to read the data, determines a current temperature associated with the memory sub-system and selects an individual multiplier for an individual RD counter associated with the individual memory component based on the current temperature associated with the memory sub-system. The controller increments the individual RD counter based on the individual multiplier to control performance of an individual media management operation.

In some examples, the controller compares a current value of the individual RD counter to a threshold value in response to incrementing the individual RD counter. The controller performs the individual media management operation on the individual memory component in response to determining that the current value of the individual RD counter transgresses the threshold value. In some cases, the individual memory component includes one or more memory dies. The individual memory component can include one or more memory blocks or one or more WLs.

The individual media management operation can include an RD scan operation including reading data from the individual memory component and computing a RBER for the data read from the individual memory component. In some cases, the controller compares the RBER to an RBER threshold and refreshes or folds the data stored in the individual memory component in response to comparing the RBER to the RBER threshold.

The controller can identify a subset of WLs of the individual memory component that are associated with increased temperature sensitivity relative to other WLs of the individual memory component. In some cases, the controller reads the data from only the subset of WLs to compute the RBER for the read disturb operation.

In some examples, the controller determines the current temperature by accessing a temperature measurement from a sensor of the set of memory components. The controller stores a separate RD counter for each of the set of memory components. In some cases, the controller stores a table that associates different temperature ranges with respective multipliers. The table can include a first temperature range associated with a first multiplier and a second temperature range associated with a second multiplier, the second multiplier being greater than the first multiplier.

The controller can determine that the current temperature corresponds to the second temperature range and, in response to determining that the current temperature corresponds to the second temperature range, can set the individual multiplier to a value of the second multiplier that is associated in the table with the second temperature range. In some cases, the controller receives an additional request to read the data from the individual memory component of the set of memory components. The controller, in response to receiving the additional request to read the data, determines a new current temperature associated with the memory sub-system. The controller determines that the new current temperature corresponds to the first temperature range. The controller increments the individual RD counter based on the first multiplier associated with the first temperature range in response to the additional request to read the data.

In some cases, the first temperature range includes temperatures below a first temperature, the second temperature range includes temperatures between the first temperature and a second temperature, and a third temperature range associated with a third multiplier includes temperatures above the second temperature. The multipliers for the different temperature ranges can be generated based on characteristics of a silicon device implementing the memory sub-system. In some cases, the individual RD counter is incremented by different amounts for different requests to read the data from the individual memory component based on a temperature associated with the memory sub-system when each respective one of the different requests is received.

Though various examples are described herein as being implemented with respect to a memory sub-system (e.g., a controller of the memory sub-system), some or all of the portions of an example can be implemented with respect to a host system, such as a software application or an operating system of the host system.

FIG. 1 illustrates an example computing environment 100 including a memory sub-system 110, in accordance with some examples. The memory sub-system 110 can include media, such as memory components 112A to 112N (also hereinafter referred to as “memory devices”). The memory components 112A to 112N can be volatile memory devices, non-volatile memory devices, or a combination of such. The memory components 112A to 112N can be implemented by individual dies, such that a first memory component 112A can be implemented by a first memory die (or a first collection of memory dies) and a second memory component 112N can be implemented by a second memory die (or a second collection of memory dies).

In some examples, the first memory component 112A or group of memory components including the first memory component 112A can be associated with a first temperature threshold (or tolerance) and/or reliability (capability) grade, value or measure. Reliability grade, value or measure is used interchangeably throughout and can have the same meaning. Temperature threshold and temperature tolerance measure is used interchangeably throughout and can have the same meaning. The second memory component 112N or group of memory components including the second memory component 112N can be associated with a second temperature threshold and/or reliability (capability) grade, value or measure. In some examples, each memory component 112A to 112N can store respective configuration data that specifies the respective temperature threshold. In some examples, a memory or register can be associated with all of the memory components 112A to 112N which can store a table that maps different groups, bins or sets of the memory components 112A to 112N to respective temperature thresholds. In some examples, each of the memory components 112A to 112N can store a write temperature that has been measured when data was written to the respective memory component 112A to 112N. This data can be stored in a separate write temperature register of each memory component 112A to 112N and/or as part of the underlying data stored to the respective memory component 112A to 112N.

In some examples, the memory sub-system 110 is a storage system. A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The computing environment 100 can include a host system 120 that is coupled to a memory system. The memory system can include one or more memory sub-systems 110. In some examples, the host system 120 is coupled to different types of memory sub-system 110. FIG. 1 illustrates one example of a host system 120 coupled to one memory sub-system 110. The host system 120 uses the memory sub-system 110, for example, to write data to the memory sub-system 110 and read data from the memory sub-system 110. As used herein, “coupled to” generally refers to a connection between components, which can be an indirect communicative connection or direct communicative connection (e.g., without intervening components), whether wired or wireless, including connections such as electrical, optical, magnetic, etc.

The host system 120 can be a computing device such as a desktop computer, laptop computer, network server, mobile device, embedded computer (e.g., one included in a vehicle, industrial equipment, or a networked commercial device), or such computing device that includes a memory and a processing device. The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL), a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory components 112A to 112N when the memory sub-system 110 is coupled with the host system 120 by the PCIe or CXL interface. The physical host interface can provide an interface for passing control, address, data, and other signals between the memory sub-system 110 and the host system 120.

The memory components 112A to 112N can include any combination of the different types of non-volatile memory components and/or volatile memory components. An example of non-volatile memory components includes NOR-and (NAND)-type flash memory. Each of the memory components 112A to 112N can include one or more arrays of memory cells such as single-level cells (SLCs) or multi-level cells (MLCs) (e.g., TLCs or QLCs). In some examples, a particular memory component 112 can include both an SLC portion and an MLC portion of memory cells. Each of the memory cells can store one or more bits of data (e.g., blocks) used by the host system 120. Although non-volatile memory components such as NAND-type flash memory are described, the memory components 112A to 112N can be based on any other type of memory, such as a volatile memory.

In some examples, the memory components 112A to 112N can be, but are not limited to, random access memory (RAM), read-only memory (ROM), dynamic random access memory (DRAM), synchronous dynamic random access memory (SDRAM), phase change memory (PCM), magnetoresistive random access memory (MRAM), (NOR) flash memory, electrically erasable programmable read-only memory (EEPROM), and a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write-in-place operation, where a non-volatile memory cell can be programmed without the non-volatile memory cell being previously erased. Furthermore, the memory cells of the memory components 112A to 112N can be grouped as memory pages, WLs, planes, blocks, or sub-blocks that can refer to a unit of the memory component 112 used to store data. In general, the memory pages, WLs, sub-blocks, and/or blocks are collectively or individually referred to as memory components.

The memory sub-system controller 115 can communicate with the memory components 112A to 112N to perform operations such as reading data, writing data, or erasing data at the memory components 112A to 112N and other such operations. The memory sub-system controller 115 can communicate with the memory components 112A to 112N to perform various memory management operations, such as different scan rates, different scan frequencies, different wear leveling, different read disturb management operations, such as read disturb scan operations, different near miss ECC operations, folding operations, preventing folding operations from being performed, and/or different dynamic data refresh operations.

The memory sub-system controller 115 can include hardware such as one or more integrated circuits and/or discrete components, one or more thermometers (used to measure a current operating temperature of the memory sub-system 110 and/or the memory components 112A to 112N or ambient temperature), a buffer memory, and/or a combination thereof. In some examples, the output of the one or more thermometers can be used to determine a current write temperature to be stored in association with data on the memory components 112A to 112N.

The memory sub-system controller 115 can be a microcontroller, special-purpose logic circuitry (e.g., a field programmable gate array (FPGA), an application specific integrated circuit (ASIC), etc.), or another suitable processor. The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120. In some examples, the local memory 119 can include memory registers storing memory pointers, fetched data, and so forth. The local memory 119 can also include read-only memory (ROM) for storing microcode. While the example memory sub-system 110 in FIG. 1 has been illustrated as including the memory sub-system controller 115, in another example, a memory sub-system 110 may not include a memory sub-system controller 115, and can instead rely upon external control (e.g., provided by an external host, or by a processor 117 or controller separate from the memory sub-system 110).

In general, the memory sub-system controller 115 can receive commands or operations from the host system 120 and can convert the commands or operations into instructions or appropriate commands to achieve the desired access to the memory components 112A to 112N. In some examples, the commands or operations received from the host system 120 can specify configuration data for the memory components 112N to 112N. The configuration data can include a table that associates different temperature ranges with corresponding RD counter multiplier values. The configuration data can define different read disturb conditions or criteria, such as different read count thresholds that are used to control execution and triggering of read disturb scan operations for different memory components 112A to 112N when an individual RD counter for a memory component reaches the read count threshold. For example, the configuration data can associate a first temperature range with a first RD counter multiplier value. The configuration data can associate a second temperature range with a second RD counter multiplier value. The configuration data can associate a third temperature range with a third RD counter multiplier value. The first, second and third RD counter multiplier values can be different values or in part the same values. Any other quantities of temperature ranges and corresponding RD counter multiplier value can be stored in the configuration data (e.g., as a table).

The memory sub-system controller 115 can be responsible for other memory management operations, such as wear leveling operations, garbage collection operations, error detection and error-correcting code (ECC) operations, encryption operations, caching operations, media scans, data refreshing, read disturb operations, and address translations. The memory sub-system controller 115 can further include host interface circuitry to communicate with the host system 120 via the physical host interface. The host interface circuitry can convert the commands received from the host system 120 into command instructions to access the memory components 112A to 112N as well as convert responses associated with the memory components 112A to 112N into information for the host system 120.

The memory sub-system 110 can also include additional circuitry or components that are not illustrated. In some examples, the memory sub-system 110 can include a cache or buffer (e.g., DRAM or other temporary storage location or device) and address circuitry (e.g., a row decoder and a column decoder) that can receive an address from the memory sub-system controller 115 and decode the address to access the memory components 112A to 112N.

The memory devices can be raw memory devices (e.g., NAND), which are managed externally, for example, by an external controller (e.g., memory sub-system controller 115). The memory devices can be managed memory devices (e.g., managed NAND), which is a raw memory device combined with a local embedded controller (e.g., local media controllers) for memory management within the same memory device package. Any one of the memory components 112A to 112N can include a media controller (e.g., media controller 113A and media controller 113N) to manage the memory cells of the memory component (e.g., to perform one or more memory management operations), to communicate with the memory sub-system controller 115, and to execute memory requests (e.g., read or write) received from the memory sub-system controller 115.

The memory sub-system controller 115 can include a media operations manager 122. The media operations manager 122 can be configured to determine a current temperature of the memory sub-system 110 that includes the memory components 112A to 112N and can access a table (e.g., from the configuration data) that maps different temperature ranges to corresponding RD counter multiplier values. The media operations manager 122 can access a temperature measurement from one or more sensors of the memory components 112A to 112N to determine the current temperature of the memory sub-system 110 in response to receiving a request to read data from an individual memory component. The media operations manager 122 can select or identify an RD multiplier counter value based on the table and the current temperature that is measured. The memory sub-system controller 115 can, in response, adjust the RD counter associated with the memory component of the set of memory components 112A to 112N being read based on the selected or identified RD multiplier counter value. The memory sub-system controller 115 can perform an individual media management operation on the individual memory component, such as by performing a read disturb scan operation when the adjusted RD counter is determined to transgress an RD threshold value. This increases the efficiency of operating memory systems because the memory controller dynamically selects or sets the frequency at which read disturb scan operations or other memory management operations are performed for the memory sub-system 110 based on temperature of the memory sub-system, which improves the overall efficiency of operating the memory sub-system 110.

Depending on the examples, the media operations manager 122 can comprise logic (e.g., a set of transitory or non-transitory machine instructions, such as firmware) or one or more components that causes the media operations manager 122 to perform operations described herein. The media operations manager 122 can comprise a tangible or non-tangible unit capable of performing operations described herein. Further details with regards to the operations of the media operations manager 122 are described below.

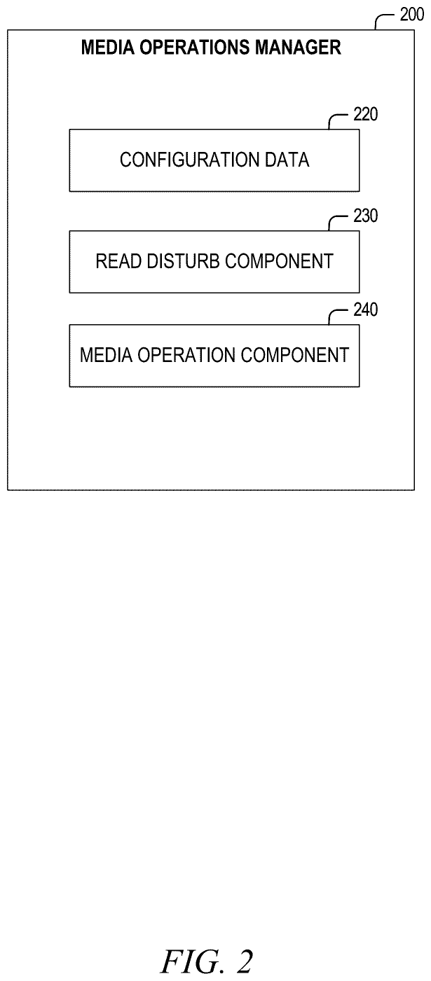

FIG. 2 is a block diagram of an example media operations manager 200 (corresponding to media operations manager 122), in accordance with some examples. As illustrated, the media operations manager 200 includes configuration data 220, a read disturb component 230, and a media operation component 240. For some examples, the media operations manager 122 can differ in components or arrangement (e.g., less or fewer components) from what is illustrated in FIG. 2.

The configuration data 220 accesses and/or stores configuration data associated with the memory components 112A to 112N. In some examples, the configuration data 220 is programmed into the media operations manager 122. For example, the media operations manager 122 can communicate with the memory components 112A to 112N to obtain the configuration data and store the configuration data 220 locally on the media operations manager 122. In some examples, the media operations manager 122 communicates with the host system 120. The host system 120 receives input from an operator or user that specifies parameters including temperature tolerances or RD thresholds of different bins, groups, blocks, WLs, or sets of the memory components 112A to 112N. The media operations manager 122 receives the configuration data from the host system 120 and stores the configuration data in the configuration data 220.

The read disturb component 230 accesses a temperature sensor associated with the memory sub-system 110 to determine a current temperature of the memory sub-system 110. The read disturb component 230 can then search the configuration data 220 to identify a first temperature range (e.g., between 55 degrees Celsius and 90 degrees Celsius) in which the current temperature falls. For example, the component 230 can determine that the current temperature is below the first temperature range. The read disturb component 230 can, in response, determine whether the current temperature is within a second temperature range. Based on these determinations, the read disturb component 230 obtains an RD counter multiplier value associated with the identified temperature range within which the current temperature falls. For example, the read disturb component 230 can obtain a first RD counter multiplier value in response to determining that the current temperature falls within the first temperature range. As another example, the read disturb component 230 can obtain a second RD counter multiplier value in response to determining that the current temperature falls within the second temperature range. In some cases, if the current temperature falls outside of all the ranges defined in the table, the read disturb component 230 obtains a default RD counter multiplier value (e.g., the value one).

The read disturb component 230 can obtain a current read count value associated with an individual memory component of the memory components 112A to 112N that is being read (e.g., by the memory sub-system controller 115 and/or by the host system 120). The read disturb component 230 can increment or otherwise adjust the current read count value based on the RD counter multiplier value obtained from the table. For example, the RD counter multiplier value obtained from the table can be a whole number or fractional number. Specifically, the RD counter multiplier value can be the number two. In such cases, the read disturb component 230 increments the current read count value by two.

The component 230 can compare the current read count value associated with the individual memory component with the read count threshold associated with the memory component. The component 230 can determine that the current read count value transgresses the read count threshold value. In such cases, the component 230 can instruct the media operation component 240 to perform a media management operation on the individual memory component, such as a read disturb scan. The media operation component 240 can identify a set of predetermined WLs of the individual memory component that are prone to temperature variation or that have different read performances across different ranges of temperatures more than other WLs. The media operation component 240 can then read data from the set of predetermined WLs only and compare the RBER of the read data to an RBER threshold. If the RBER transgresses the RBER threshold, the media operation component 240 can fold the data or rewrite or refresh the data stored in the individual memory component to another memory component or memory block.

At a later time, the read disturb component 230 can receive an additional request to read the same memory component. At that time when the additional request to read the same memory component is received, the read disturb component 230 can again determine the current temperature. Now, the read disturb component 230 may determine that the current temperature falls within a second temperature range corresponding to a different RD counter multiplier value (e.g., 1.6). In such cases, the read disturb component 230 obtains the current read count associated with the memory component and increments the read count value by 1.6.

The component 230 can compare the current read count value associated with the individual memory component with the read count threshold associated with the memory component. The component 230 can determine that the current read count value transgresses the read count threshold value. In such cases, the component 230 can instruct the media operation component 240 to perform a media management operation on the individual memory component, such as a read disturb scan. The media operation component 240 can identify a set of predetermined WLs of the individual memory component that are prone to temperature variation or that have different read performances across different ranges of temperatures more than other WLs. The media operation component 240 can then read data from the set of predetermined WLs only and compare the RBER of the read data to an RBER threshold. If the RBER transgresses the RBER threshold, the media operation component 240 can fold the data or rewrite or refresh the data stored in the individual memory component to another memory component or memory block.

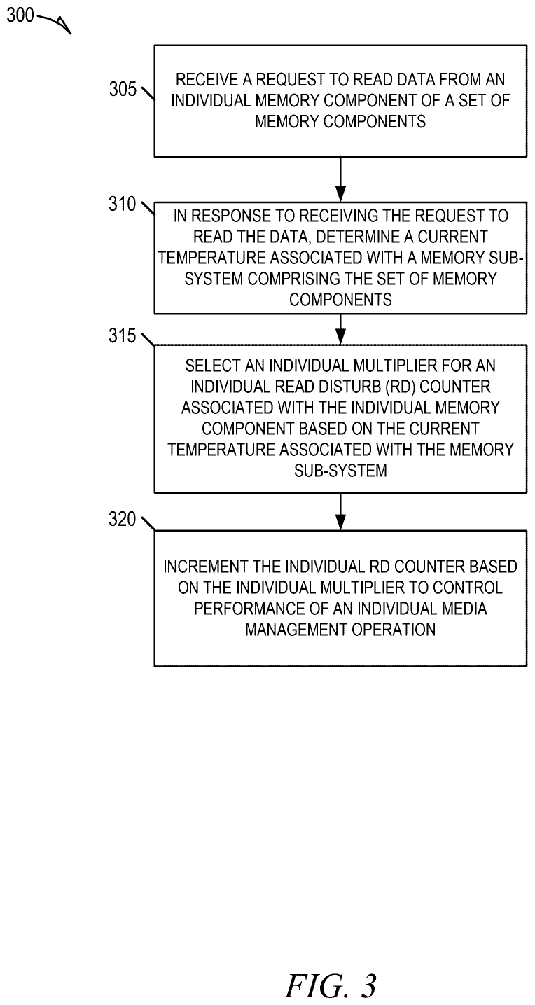

FIG. 3 is a flow diagram of an example method 300 to perform media management operations based on temperature of the memory sub-system 110, in accordance with some examples. The method 300 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 300 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 3, the method (or process) 300 begins at operation 305, with a media operations manager 122 of a memory sub-system 110 receiving a request to read data from an individual memory component of the set of memory components. At operation 310, the media operations manager 122 of the memory sub-system 110 in response to receiving the request to read the data, determines a current temperature associated with the memory sub-system 110. Thereafter, at operation 315, the media operations manager 122 selects an individual multiplier for an individual read disturb (RD) counter associated with the individual memory component based on the current temperature associated with the memory sub-system and, at operation 320, increments the individual RD counter based on the individual multiplier to control performance of an individual media management operation.

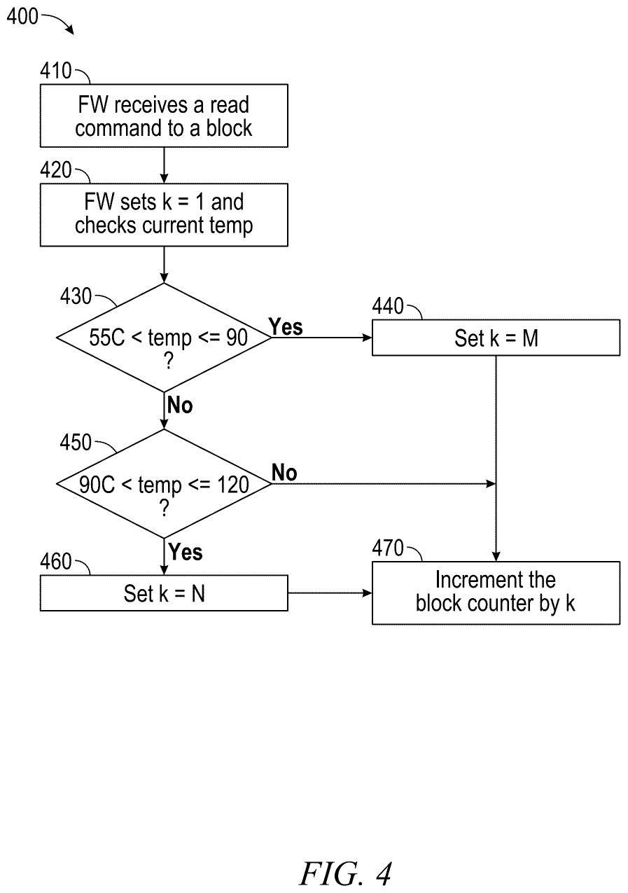

FIG. 4 is a flow diagram of an example method 400 to perform media management operations based on temperature of the memory sub-system 110, in accordance with some examples. The method 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method 400 is performed by the media operations manager 122 of FIG. 1. Although the processes are shown in a particular sequence or order, unless otherwise specified, the order of the processes can be modified. Thus, the illustrated examples should be understood only as examples, and the illustrated processes can be performed in a different order, and some processes can be performed in parallel. Additionally, one or more processes can be omitted in various examples. Thus, not all processes are required in every example. Other process flows are possible.

Referring now to FIG. 4, the method (or process) 400 begins at operation 410 where the media operations manager 200 (e.g., the firmware of the memory sub-system 110) receives a request to read data from a memory block (e.g., from the host system 120 or from the memory sub-system controller 115). In such cases, at operation 420, the media operations manager 200 sets the RD multiplier to a default value, such as the value one. Also, at operation 420, the media operations manager 200 communicates with one or more temperature sensors of the set of memory components to obtain a current temperature associated with the memory sub-system 110. The media operations manager 200, at operation 430, access an RD multiplier table to identify a range of multiple ranges of temperatures that the current temperature corresponds to or falls within. For example, the media operations manager 200 can determine if the current temperature is between 55 degrees Celsius and 90 degrees Celsius.

In response to determining that the current temperature falls or corresponds to a first temperature range (e.g., is between 55 degrees Celsius and 90 degrees Celsius), the media operations manager 200 performs operation 440. At operation 440, the media operations manager 200 sets the RD multiplier value to the multiplier value associated with the first temperature range, such as M (e.g., 2). In response to determining that the current temperature fails to fall or corresponds to the first temperature range (e.g., is not between 55 degrees Celsius and 90 degrees Celsius), the media operations manager 200 performs operation 450.

At operation 450, the media operations manager 200 determines whether the current temperature corresponds to or falls within a second temperature range (e.g., is between 90 degrees Celsius and 120 degrees Celsius). In response to determining that the current temperature falls or corresponds to the second temperature range, the media operations manager 200 performs operation 460. At operation 460, the media operations manager 200 sets the RD multiplier value to the multiplier value associated with the second temperature range, such as N (e.g., 4). In response to determining that the current temperature fails to fall or corresponds to the second temperature range, the media operations manager 200 performs operation 470. At operation 470 (e.g., after performing operation 440), the media operations manager 200 increments the RD counter associated with the memory block being requested to be read at operation 410 by the RD multiplier value (e.g., the value computed at operations 420, 440 or operation 460).

In view of the disclosure above, various examples are set forth below. It should be noted that one or more features of an example, taken in isolation or combination, should be considered within the disclosure of this application.

Example 1. A system comprising: a set of memory components of a memory sub-system; and a processing device operatively coupled to the set of memory components, the processing device being configured to perform operations comprising: receiving a request to read data from an individual memory component of the set of memory components; in response to receiving the request to read the data, determining a current temperature associated with the memory sub-system; selecting an individual multiplier for an individual read disturb (RD) counter associated with the individual memory component based on the current temperature associated with the memory sub-system; and incrementing the individual RD counter based on the individual multiplier to control performance of an individual media management operation.

Example 2. The system of Example 1, the operations comprising: comparing a current value of the individual RD counter to a threshold value in response to incrementing the individual RD counter; and performing the individual media management operation on the individual memory component in response to determining that the current value of the individual RD counter transgresses the threshold value.

Example 3. The system of any one of Examples 1-2, wherein the individual memory component comprises one or more memory dies.

Example 4. The system of any one of Examples 1-3, wherein the individual memory component comprises one or more memory blocks or one or more word lines.

Example 5. The system of any one of Examples 1-4, wherein the individual media management operation comprises a RD scan operation comprising: reading data from the individual memory component; and computing a read bit error rate (RBER) for the data read from the individual memory component.

Example 6. The system of Example 5, the operations comprising: comparing the RBER to an RBER threshold; and refreshing or folding the data stored in the individual memory component in response to comparing the RBER to the RBER threshold.

Example 7. The system of any one of Examples 5-6, the operations comprising: identifying a subset of word lines (WLs) of the individual memory component that are associated with increased temperature sensitivity relative to other WLs of the individual memory component.

Example 8. The system of Example 7, the operations comprising: reading the data from only the subset of WLs to compute the RBER for the read disturb operation.

Example 9. The system of any one of Examples 1-8, wherein determining the current temperature comprises accessing a temperature measurement from a sensor of the set of memory components.

Example 10. The system of any one of Examples 1-9, the operations comprising: storing a separate RD counter for each of the set of memory components.

Example 11. The system of any one of Examples 1-10, the operations comprising: storing a table that associates different temperature ranges with respective multipliers.

Example 12. The system of Example 11, wherein the table comprises a first temperature range associated with a first multiplier and a second temperature range associated with a second multiplier, the second multiplier being greater than the first multiplier.

Example 13. The system of Example 12, the operations comprising: determining that the current temperature corresponds to the second temperature range; and in response to determining that the current temperature corresponds to the second temperature range, setting the individual multiplier to a value of the second multiplier that is associated in the table with the second temperature range.

Example 14. The system of Example 13, the operations comprising: receiving an additional request to read the data from the individual memory component of the set of memory components; in response to receiving the additional request to read the data, determining a new current temperature associated with the memory sub-system; determining that the new current temperature corresponds to the first temperature range; and incrementing the individual RD counter based on the first multiplier associated with the first temperature range in response to the additional request to read the data.

Example 15. The system of any one of Examples 12-14, wherein the first temperature range comprises temperatures below a first temperature, the second temperature range comprises temperatures between the first temperature and a second temperature, and a third temperature range associated with a third multiplier comprises temperatures above the second temperature.

Example 16. The system of any one of Examples 11-15, wherein the multipliers for the different temperature ranges are generated based on characteristics of a silicon device implementing the memory sub-system.

Example 17. The system of any one of Examples 1-16, wherein the individual RD counter is incremented by different amounts for different requests to read the data from the individual memory component based on a temperature associated with the memory sub-system when each respective one of the different requests is received.

Example 18. A method comprising: receiving a request to read data from an individual memory component of a set of memory components; in response to receiving the request to read the data, determining a current temperature associated with a memory sub-system comprising the set of memory components; selecting an individual multiplier for an individual read disturb (RD) counter associated with the individual memory component based on the current temperature associated with the memory sub-system; and incrementing the individual RD counter based on the individual multiplier to control performance of an individual media management operation.

Example 19. The method of Example 18, comprising: comparing a current value of the individual RD counter to a threshold value in response to incrementing the individual RD counter; and performing the individual media management operation on the individual memory component in response to determining that the current value of the individual RD counter transgresses the threshold value.

Example 20. A non-transitory computer-readable storage medium comprising instructions that, when executed by a processing device, cause the processing device to perform operations comprising: receiving a request to read data from an individual memory component of a set of memory components; in response to receiving the request to read the data, determining a current temperature associated with a memory sub-system comprising the set of memory components; selecting an individual multiplier for an individual read disturb (RD) counter associated with the individual memory component based on the current temperature associated with the memory sub-system; and incrementing the individual RD counter based on the individual multiplier to control performance of an individual media management operation.

Methods and computer-readable storage medium with instructions for performing any one of the above Examples.

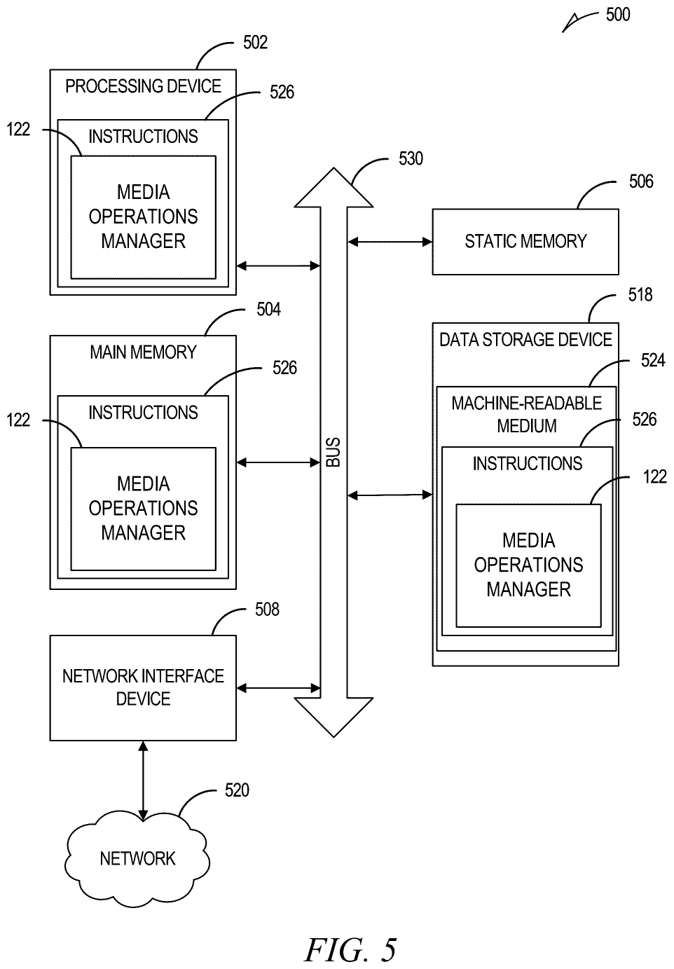

FIG. 5 illustrates an example machine in the form of a computer system 500 within which a set of instructions can be executed for causing the machine to perform any one or more of the methodologies discussed herein. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the media operations manager 122 of FIG. 1). In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a network switch, a network bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application specific integrated circuit (ASIC), a field programmable gate array (FPGA), a digital signal processor (DSP), a network processor, or the like. The processing device 502 is configured to execute instructions 526 for performing the operations and steps discussed herein. The computer system 500 can further include a network interface device 508 to communicate over a network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 implement functionality corresponding to the media operations manager 122 of FIG. 1. While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system's memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks; read-only memories (ROMs); random access memories (RAMs); erasable programmable read-only memories (EPROMs); EEPROMs; magnetic or optical cards; or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description above. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine-readable (e.g., computer-readable) storage medium such as a read-only memory (ROM), random access memory (RAM), magnetic disk storage media, optical storage media, flash memory components, and so forth.

In the foregoing specification, examples of the disclosure have been described with reference to specific example embodiments thereof. It will be evident that various modifications can be made thereto without departing from the broader examples of the disclosure as set forth in the following claims. The specification and drawings are, accordingly, to be regarded in an illustrative sense rather than a restrictive sense.

What is claimed is:

1. A system comprising:
a set of memory components of a memory sub-system; and
a processing device operatively coupled to the set of memory components, the processing device being configured to perform operations comprising:
receiving a request to read data from an individual memory component of the set of memory components;
in response to receiving the request to read the data, determining a current temperature associated with the memory sub-system;
selecting an individual multiplier for an individual read disturb (RD) counter associated with the individual memory component based on the current temperature associated with the memory sub-system; and
incrementing the individual RD counter based on the individual multiplier to control performance of an individual media management operation.

2. The system of claim 1, the operations comprising:
comparing a current value of the individual RD counter to a threshold value in response to incrementing the individual RD counter; and
performing the individual media management operation on the individual memory component in response to determining that the current value of the individual RD counter transgresses the threshold value.

3. The system of claim 1, wherein the individual memory component comprises one or more memory dies.

4. The system of claim 1, wherein the individual memory component comprises one or more memory blocks or one or more word lines.

5. The system of claim 1, wherein the individual media management operation comprises a RD scan operation comprising:
reading data from the individual memory component; and
computing a read bit error rate (RBER) for the data read from the individual memory component.

6. The system of claim 5, the operations comprising:
comparing the RBER to an RBER threshold; and
refreshing or folding the data stored in the individual memory component in response to comparing the RBER to the RBER threshold.

7. The system of claim 5, the operations comprising:
identifying a subset of word lines (WLs) of the individual memory component that are associated with increased temperature sensitivity relative to other WLs of the individual memory component.

8. The system of claim 7, the operations comprising:
reading the data from only the subset of WLs to compute the RBER for a read disturb operation.

9. The system of claim 1, wherein determining the current temperature comprises accessing a temperature measurement from a sensor of the set of memory components.

10. The system of claim 1, the operations comprising:
storing a separate RD counter for each of the set of memory components.

11. The system of claim 1, the operations comprising:
storing a table that associates different temperature ranges with respective multipliers.

12. The system of claim 11, wherein the table comprises a first temperature range associated with a first multiplier and a second temperature range associated with a second multiplier, the second multiplier being greater than the first multiplier.

13. The system of claim 12, the operations comprising:
determining that the current temperature corresponds to the second temperature range; and
in response to determining that the current temperature corresponds to the second temperature range, setting the individual multiplier to a value of the second multiplier that is associated in the table with the second temperature range.

14. The system of claim 13, the operations comprising:
receiving an additional request to read the data from the individual memory component of the set of memory components;
in response to receiving the additional request to read the data, determining a new current temperature associated with the memory sub-system;
determining that the new current temperature corresponds to the first temperature range; and
incrementing the individual RD counter based on the first multiplier associated with the first temperature range in response to the additional request to read the data.

15. The system of claim 12, wherein the first temperature range comprises temperatures below a first temperature, the second temperature range comprises temperatures between the first temperature and a second temperature, and a third temperature range associated with a third multiplier comprises temperatures above the second temperature.

16. The system of claim 11, wherein the multipliers for the different temperature ranges are generated based on characteristics of a silicon device implementing the memory sub-system.

17. The system of claim 1, wherein the individual RD counter is incremented by different amounts for different requests to read the data from the individual memory component based on a temperature associated with the memory sub-system when each respective one of the different requests is received.

18. A method comprising:
receiving a request to read data from an individual memory component of a set of memory components;
in response to receiving the request to read the data, determining a current temperature associated with a memory sub-system comprising the set of memory components;
selecting an individual multiplier for an individual read disturb (RD) counter associated with the individual memory component based on the current temperature associated with the memory sub-system; and
incrementing the individual RD counter based on the individual multiplier to control performance of an individual media management operation.

19. The method of claim 18, comprising:
comparing a current value of the individual RD counter to a threshold value in response to incrementing the individual RD counter; and
performing the individual media management operation on the individual memory component in response to determining that the current value of the individual RD counter transgresses the threshold value.

20. A non-transitory computer-readable storage medium comprising instructions that, when executed by a processing device, cause the processing device to perform operations comprising:
receiving a request to read data from an individual memory component of a set of memory components;
in response to receiving the request to read the data, determining a current temperature associated with a memory sub-system comprising the set of memory components;
selecting an individual multiplier for an individual read disturb (RD) counter associated with the individual memory component based on the current temperature associated with the memory sub-system; and
incrementing the individual RD counter based on the individual multiplier to control performance of an individual media management operation.
